(19) United States
(12) Patent Application Publication
(10) Pub. No.: US 2026/0190759 A1
(43) Pub. Date: Jul. 2, 2026

(54) DISPLAY APPARATUS

(71) Applicant: LG Display Co., Ltd., Seoul (KR)

(72) Inventors: Hyunjik BAE, Paju-si (KR); Jungseop YOON, Paju-si (KR); ByungJune MUN, Paju-si (KR)

(73) Assignee: LG Display Co., Ltd., Seoul (KR)

(21) Appl. No.: 19/407,842

(22) Filed: Dec. 3, 2025

(30) Foreign Application Priority Data
Dec. 31, 2024 (KR) 10-2024-0201838

(51) Int. Cl. H10K 59/80; H10K 59/122; H10K 59/131

(52) U.S. Cl. CPC H10K 59/80521; H10K 59/122; H10K 59/131; H10K 59/879

(57) ABSTRACT

A display apparatus includes a display area having a plurality of subpixels. Each subpixel of the plurality of subpixels includes a first light emitting element, a second light emitting element, and a pixel circuit commonly connected to the first and second light emitting elements. A first cathode electrode of the first light emitting element and a second cathode electrode of the second light emitting element are separated from each other. Supply voltages applied to the first and second cathode electrodes are varied according to a viewing angle control mode so that one of the light emitting elements emits light for a wide viewing angle and the other emits light for a narrow viewing angle. The configuration allows electrical switching between wide and narrow viewing modes without the use of mechanical filters, thereby enabling an adjustable viewing angle with high brightness and image quality.

### CROSS-REFERENCE TO RELATED APPLICATION

This application claims the benefit of priority of the Republic of Korea Patent Application No. 10-2024-0201838 filed on Dec. 31, 2024, which is hereby incorporated by reference in its entirety.

### BACKGROUND

### Technical Field

This present disclosure relates to a display apparatus capable of controlling a viewing angle.

### Description of the Related Art

The display apparatuses may be used in various electronic devices.

Among the display apparatuses installed in automobiles, the display apparatus disposed in front of the passenger seat needs to limit the driver's field of view depending on the driver's driving situation.

The display apparatuses need to limit the viewing angle according to user needs for privacy and information protection.

The display apparatuses may use security films to limit the viewing angle of the displayed image. However, security films significantly reduce the brightness of the display apparatus, and the viewing angle is limited, which may cause inconvenience to the user.

### BRIEF SUMMARY

The present disclosure relates to a display apparatus capable of dynamically controlling its viewing angle by electrically switching between wide and narrow viewing modes without the use of mechanical filters or privacy films. Each subpixel includes two light emitting elements, one for a wide viewing angle and another for a narrow viewing angle, sharing a common anode but having separate cathode electrodes. By varying the supply voltages applied to these cathodes, the apparatus selectively activates either light emitting element, enabling a share or privacy mode with minimal brightness loss.

The display includes distinct lens structures positioned over each light emitting element. A first lens disperses light broadly for wide angle viewing, while a second lens narrows the light emission for privacy. This optical differentiation, combined with independent electrical control, allows precise modulation of the viewing angle at the subpixel level. The configuration further includes a unified pixel circuit and power management unit that coordinate voltage switching, ensuring consistent color, brightness, and response across the display panel.

The arrangement also employs alternating cathode line configurations and carefully layered optical, touch sensing, and encapsulation components to maintain image quality while minimizing reflection, which is particularly useful in automotive and flexible display applications. The technical concept integrates dual light emission paths, independent cathode control, and specialized lens structures to achieve an electronically switchable privacy display that maintains high brightness and adaptability.

Accordingly, the present disclosure is directed to providing a display apparatus that substantially obviate one or more problems due to limitations and disadvantages of the related art.

In one aspect, the present disclosure provides a display apparatus capable of controlling a viewing angle.

Additional advantages and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and claims hereof as well as the appended drawings.

A display apparatus according to one embodiment of the present disclosure comprises a display area disposing a plurality of subpixels, wherein each of the plurality of subpixels includes a first light emitting element, a second light emitting element, and a pixel circuit commonly connected to the first and second light emitting elements, wherein a first cathode electrode of the first light emitting element and a second cathode electrode of the second light emitting element are separated from each other, and supply voltages applied to the first and second cathode electrodes are varied according to a viewing angle control mode.

It is to be understood that both the foregoing general description and the following detailed description of the present disclosure are exemplary and explanatory and are intended to provide further explanation of the disclosure.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic diagram illustrating a display apparatus configuration according to one embodiment of the present disclosure.

FIG. 2 is a cross-sectional view schematically showing the structure of a display panel according to one embodiment of the present disclosure.

FIG. 3 is a schematic diagram illustrating a subpixel configuration according to one embodiment of the present disclosure.

FIGS. 4A and 4B are diagrams illustrating the structure of the first and second light control elements according to one embodiment of the present disclosure.

FIG. 5 is a drawing schematically illustrating a pixel structure in a display panel according to one embodiment.

FIG. 6 is an equivalent circuit diagram illustrating a subpixel configuration according to one embodiment of the present disclosure.

FIG. 7 is a schematic diagram illustrating a gate driving circuit configuration according to one embodiment of the present disclosure.

FIG. 8 is a drawing illustrating a cathode electrode division structure of a display apparatus according to one embodiment of the present disclosure.

FIG. 9 is a cross-sectional view illustrating a subpixel configuration of a display apparatus according to one embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present disclosure are used, another part may also be present unless “only” is used. The terms in a singular form may include plural forms unless noted to the contrary.

In construing an element, the element is construed as including an error range even if there is no explicit description thereof.

In describing a positional relationship, for example, when the positional order is described as “on,” “above,” “below,” “beneath,” and “next,” the case of no contact therebetween may be included, unless “just” or “direct” is used.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically. The embodiments of the present disclosure may be carried out independently from each other, or may be carried out together in a co-dependent relationship.

Hereinafter, the aspect of the present disclosure will be described with reference to the accompanying drawings. Since a scale of each of elements shown in the accompanying drawings is different from an actual scale for convenience of description, the present disclosure is not limited to the shown scale. Further, all the components of each display apparatus, display device, and display panel according to all aspects of the present disclosure are operatively coupled and configured.

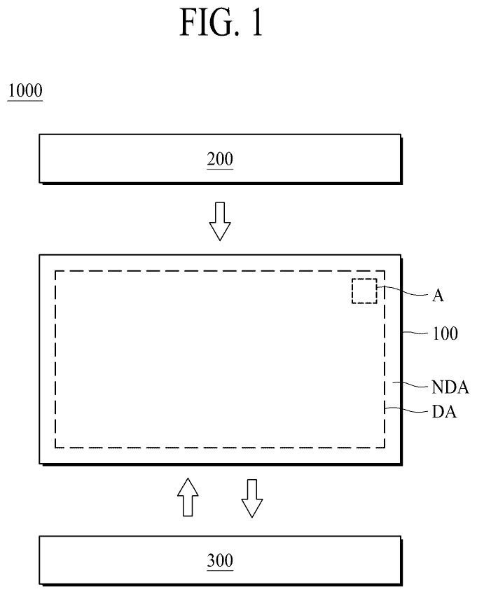

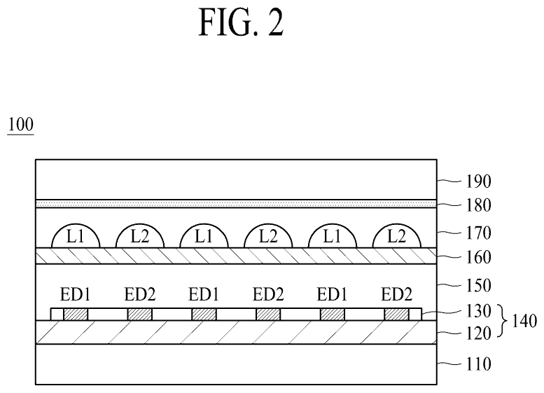

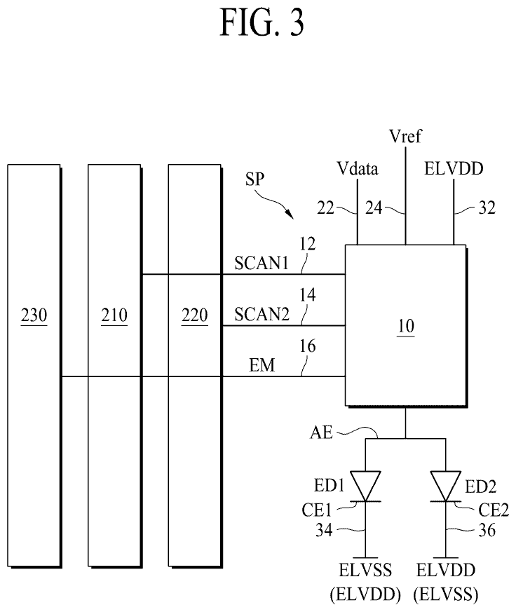

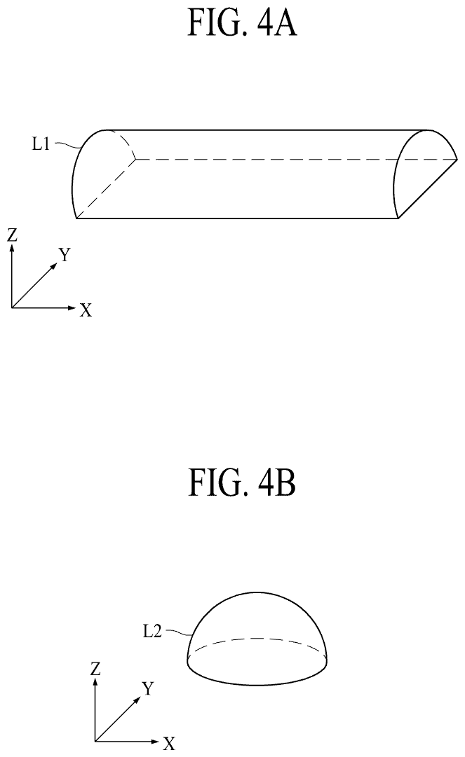

FIG. 1 is a schematic diagram illustrating a configuration of a display apparatus according to one embodiment, FIG. 2 is a cross-sectional diagram schematically illustrating a structure of a display panel according to one embodiment, FIG. 3 is a schematic diagram illustrating a subpixel configuration according to one embodiment, and FIGS. 4A and 4B are diagrams illustrating structures of first and second light control elements according to one embodiment.

A display apparatus 1000 according to one embodiment may provide both a display function for displaying an image and a touch sensing function for sensing the presence or absence of a user's touch and/or touch coordinates.

The display apparatus 1000 according to one embodiment may be an electro-luminescent display or a micro light emitting diode display apparatus including a touch sensor. The electro-luminescent display apparatus including a touch sensor may be an organic light emitting diode (OLED) display apparatus, a quantum-dot light emitting diode (QD) display apparatus, or an inorganic light emitting diode (ILD) display apparatus.

Referring to FIG. 1, a display apparatus 1000 may include a display panel 100, a display driving circuit 200 that drives the display panel 100, and a touch sensing circuit 300 that drives and senses a touch sensor array built into the display panel 100. The display apparatus 1000 may further include a power management circuit that generates and supplies a plurality of power voltages required for the operation of the display panel 100, the display driving circuit 200, and the touch sensing circuit 300.

The display panel 100 may be a rigid display panel or a flexible display panel capable of changing shape, such as a foldable, bendable, rollable, or stretchable display panel.

The display panel 100 may include a display area DA for displaying an image, and a non-display area NDA, which is a bezel area disposed on the outer edge surrounding the display area DA. The display panel 100 may further include a touch sensor array that is arranged in the display area DA and senses a user's touch.

The display panel 100 may display an image using a display area DA in which a plurality of subpixels are arranged in a matrix form. The pixel matrix of the display area DA may include a plurality of row lines composed of a plurality of subpixels arranged in a first direction X and a plurality of column lines composed of a plurality of subpixels arranged in a second direction Y. The display panel 100 may include a plurality of signal lines including a plurality of gate lines, a plurality of data lines, a plurality of power lines, or the like, connected to a plurality of subpixels.

The plurality of subpixels may include a red subpixel that emits red light, a green subpixel that emits green light, and a blue subpixel that emits blue light. The plurality of subpixels may further include a white subpixel that emits white light. A unit pixel may include at least two subpixels.

The display driving circuit 200 may include a data driving circuit that supplies data signals to a plurality of data lines of the display panel 100, a gate driving circuit that supplies gate signals to a plurality of gate lines, a timing controller that controls the operations of the data driving circuit and the gate driving circuit, or the like.

The touch sensing circuit 300 may include a touch driving circuit that supplies a touch driving signal to a touch sensor array built into a display panel 100 and receives a readout signal from the touch sensor array, and generates sensing data. The touch sensing circuit 300 may further include a touch controller that detects the presence or absence of a touch and the touch coordinate position based on the sensing data supplied from the touch driving circuit.

The touch sensor array may use a self-capacitance method that senses changes in self-capacitance according to touch, or a mutual-capacitance method that senses changes in mutual-capacitance according to touch.

The display panel 100 according to one embodiment may be capable of controlling a viewing angle according to a viewing angle control mode. The display area DA of the display panel 100 may display an image in a first viewing angle control mode in which a viewing angle in a first direction is relatively wide, or in a second viewing angle control mode in which a viewing angle in the first direction is narrower than the first viewing angle control mode. The first viewing angle control mode may be expressed as a wide viewing angle control mode or a share mode. The second viewing angle control mode may be expressed as a narrow viewing angle control mode or a privacy mode. The display area DA of the display panel 100 may be driven in a switchable privacy mode (SPM) in which the share mode and the privacy mode may be switched.

Referring to FIG. 2, the display panel 100 according to one embodiment may include a pixel array 140. The pixel array 140 may include a circuit element layer 120 including a plurality of transistors and a plurality of signal lines, or the like, disposed on a substrate 110 and a light emitting element layer 130 including a plurality of light emitting elements ED1 and ED2 disposed on the circuit element layer 120. The display panel 100 may further include an encapsulation layer 150 disposed on the pixel array 140 to seal the light emitting element layer 130. The display panel 100 may further include a touch sensor array 160 including a plurality of sensor electrodes disposed on the encapsulation layer 150, and a light control array 170 including a plurality of light control elements L1 and L2 disposed on the touch sensor array 160. The display panel 100 may further include a cover substrate 190 bonded to the light control array 170 by an optical clear adhesive (OCA) 180.

The touch sensor array 160 according to one embodiment may include a sensor electrode, a dummy electrode, and a black matrix arranged to overlap with a non-emitting region of a light emitting element ED1 and ED2. At least one of the sensor electrode, the dummy electrode, and the black matrix according to one embodiment may overlap with an end portion of a light control element L1 and L2 to act as a barrier that blocks light, thereby preventing light leakage due to light leakage or reflected light. At least one of the sensor electrode, the dummy electrode, and the black matrix according to one embodiment may not overlap with an end portion of a light control element L1 for a wide viewing angle, thereby preventing a limitation of the wide viewing angle.

Referring to FIGS. 2 and 3, a subpixel SP according to an embodiment capable of controlling a viewing angle may include a first light emitting element ED1, a second light emitting element ED2, and a pixel circuit 10 for driving the first and second light emitting elements ED1 and ED2, and a first light control element L1 may be overlapped on the first light emitting element ED1, and a second light control element L2 may be overlapped on the second light emitting element ED2.

According to one embodiment, a subpixel SP may drive a first light emitting element ED1 in a first viewing angle control mode and emit light having a first viewing angle through a first light control element L1. The subpixel SP may drive a second light emitting element ED2 in a second viewing angle control mode and emit light having a second viewing angle narrower than the first viewing angle through a second light control element L2.

The first cathode electrode CE1 of the first light emitting element ED1 and the second cathode electrode CE2 of the second light emitting element ED2 are separated so that the first light emitting element ED1 and the second light emitting element ED2 may be driven independently according to the viewing angle control mode.

In the first viewing angle control mode, a low-potential power supply voltage ELVSS is supplied to the first cathode electrode CE1 of the first light emitting element ED1 so that the first light emitting element ED1 may emit light by driving the pixel circuit 10, while a high-potential power supply voltage ELVDD is supplied to the second cathode electrode CE2 of the second light emitting element ED2 so that emission of the second light emitting element ED2 may be prevented.

In the second viewing angle control mode, the low-potential power supply voltage ELVSS is supplied to the second cathode electrode CE2 of the second light emitting element ED2 so that the second light emitting element ED2 may emit light by driving the pixel circuit 10, whereas the high-potential power supply voltage ELVDD is supplied to the first cathode electrode CE1 of the first light emitting element ED1 so that emission of the first light emitting element ED1 may be prevented.

Referring to FIG. 3, a gate driving circuit according to one embodiment may include a plurality of scan driving circuits 210 and 220 and a light emission control driving circuit 230. The gate driving circuit may be disposed in at least one of a plurality of non-display areas NDA of the display panel 100.

According to one embodiment, a pixel circuit 10 of a subpixel SP may receive a data voltage Vdata from a data driving circuit through one data line 22. A pixel circuit 10 of a subpixel SP may receive first and second scan signals SCAN1 and SCAN2 from first and second scan driving circuits 210, 220 through first and second gate lines 12, 14. A pixel circuit 10 of a subpixel SP may receive an emission control signal EM from an emission control driving circuit 230 through a third gate line 16. A pixel circuit 10 of a subpixel SP may receive the high-potential power supply voltage ELVDD from a power management circuit through a first power line 32, and a reference voltage Vref through a reference line 24.

The first cathode electrode CE1 of the first light emitting element ED1 may be supplied with either the low-potential power voltage ELVSS or the high-potential power voltage ELVDD from a power management circuit through a second power line 34 depending on the viewing angle control mode. The second cathode electrode CE2 of the second light emitting element ED2 may be supplied with either the low-potential power voltage ELVSS or the high-potential power voltage ELVDD from a power management circuit through a third power line 36 depending on the viewing angle control mode, and may be supplied with a power voltage opposite to that of the first cathode electrode CE1 of the first light emitting element ED1.

Referring to FIG. 4A, the first light control element L1 may have a half-cylindrical lens structure that is elongated in the first direction X, but is not limited to this lens structure. Referring to FIG. 4B, the second light control element L2 may have a half-spherical lens structure, but is not limited to this lens structure. In one embodiment, the first light control element L1 and the second light control element L2 may control (limit) the viewing angle in the first direction X differently, and control (limit) the viewing angle in the second direction Y equally.

According to one embodiment, the light control elements L1, L2 may be formed of a fluid material, a semi-fluid material, or a solid. The material and configuration of the light control elements L1 and L2 are not limited to the examples described above. In addition, depending on the case, the light control elements L1 and L2 may be referred to as a light control layer, a light control configuration, a lens, or a viewing angle control unit, but are not limited to these terms.

In FIGS. 4A and 4B, the first direction X may represent the left-right direction (horizontal direction) of the display panel 100, the second direction Y may represent the up-down direction (vertical direction) of the display panel 100, and the third direction Z may represent the front-back direction (thickness direction) of the display panel 100.

In the first viewing angle control mode, each subpixel SP of the display panel 100 drives the first light emitting element ED1 and does not limit the path of light emitted from the first light emitting element ED1 to within a specific angle in the first direction X through the first light control element L1, thereby providing light having a wide viewing angle.

In the second viewing angle control mode, each subpixel SP of the display panel 100 may drive the second light emitting element ED2 and provide light having a narrow viewing angle by limiting the path of light emitted from the second light emitting element ED2 to within a specific cut-off angle in the first direction X through the second light control element L2.

The first light control element L1 and the second light control element L2 may control the light propagation path in the second direction Y to a narrow viewing angle by limiting it to within the cut-off angle. Accordingly, in one embodiment, when the display apparatus 1000 is applied to a vehicle, the image displayed on the display apparatus 1000 may be prevented from being reflected by the windshield of the vehicle and obstructing the driver's view.

At least one of a low-temperature poly silicon (LTPS) transistor using a low-temperature poly silicon semiconductor and an oxide transistor using a metal-oxide semiconductor may be applied to a plurality of transistors arranged in the display area DA of a display panel 100 and a non-display area NDA including a gate driving circuit. In one embodiment, the display panel 100 may be configured so that LTPS transistors and oxide transistors coexist in order to reduce power consumption.

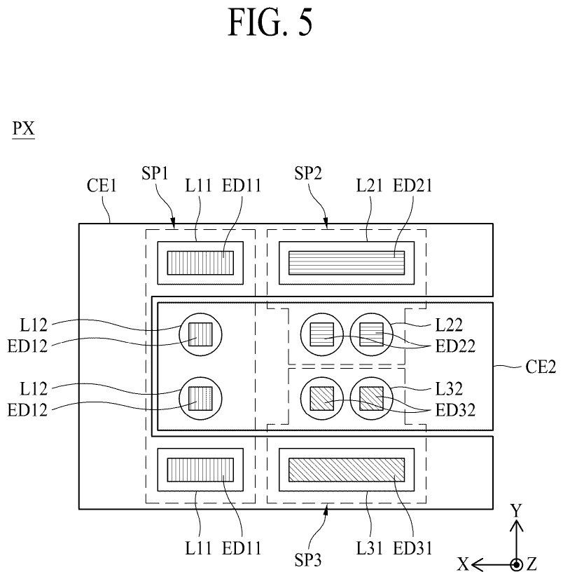

FIG. 5 is a drawing schematically illustrating a pixel structure in a display panel according to one embodiment.

Referring to FIG. 5, in a display panel according to one embodiment, each pixel PX may include first to third subpixels SP1, SP2, and SP3.

The first subpixel SP1 may include a first light emitting element ED11, a first light control element L11 overlappingly disposed on the first light emitting element ED11, a second light emitting element ED12, and a second light control element L12 overlappingly disposed on the second light emitting element ED12. The first subpixel SP1 may be a red subpixel having first and second light emitting elements ED11 and ED12 that emit red light.

The second subpixel SP2 may include a first light emitting element ED21, a first light control element L21 overlappingly disposed on the first light emitting element ED21, a second light emitting element ED22, and a second light control element L22 overlappingly disposed on the second light emitting element ED22. The second light emitting element ED22 may include a plurality of light emitting regions separated by a bank layer, and a plurality of second light control elements L22 may be respectively disposed on the plurality of light emitting regions of the second light emitting element ED22. The second subpixel SP2 may be a green subpixel having first and second light emitting elements ED21 and ED22 that emit green light.

The third subpixel SP3 may include a first light emitting element ED31, a first light control element L31 overlappingly disposed on the first light emitting element ED31, a second light emitting element ED32, and a second light control element L32 overlappingly disposed on the second light emitting element ED32. The second light emitting element ED32 may include a plurality of light emitting regions separated by a bank layer, and a plurality of second light control elements L32 may be respectively disposed on the plurality of light emitting regions of the second light emitting element ED32. The third subpixel SP3 may be a blue subpixel having first and second light emitting elements ED31 and ED32 that emit blue light.

In the first to third subpixels SP1, SP2, and SP3, the first light emitting elements ED11, ED21, and ED31 may share a first cathode electrode CE1, and the second light emitting elements ED12, ED22, and ED32 may share a second cathode electrode CE2. The first cathode electrode CE1 and the second cathode electrode CE2 may be separated.

The size of the first light emitting element ED11, ED21, and ED31 may be larger than the size of the second light emitting element ED12, ED22, and ED32. The size of the lower surface of the first light control element L11, L21, and L31 may be set to be larger than the size (size of the light emitting area) of the first light emitting element ED11, ED21, and ED31, thereby improving the light emission efficiency. The size of the lower surface of the second light control element L12, L22, and L32 may be set to be larger than the size (size of the light emitting area) of the second light emitting element ED12, ED22, and ED32, thereby improving the light emission efficiency.

In one embodiment, in order to compensate for the color-specific luminous efficiency deviation of the first light emitting elements ED11, ED21, and ED31, the sizes of the first light emitting elements ED11, ED21, and ED31 may be different for each color. In one embodiment, the sizes of the first light emitting element ED11 and the first light control element L11 of the first subpixel SP1 may be the smallest, and the sizes of the first light emitting element ED21 and the first light control element L21 of the second subpixel SP2 may be equal to or smaller than the sizes of the first light emitting element ED31 and the first light control element L31 of the third subpixel SP3.

In one embodiment, in order to compensate for the difference in luminous efficiency by color of the second light emitting elements ED12, ED22, and ED32, the size of the second light emitting elements ED12, ED22, and ED32 may be different for each color, or the number of luminous areas having the same size may be different for each color. In one embodiment, the size (number) of the second light emitting element ED12 and the second light control element L12 of the first subpixel SP1 may be the smallest, and the size (number) of the second light emitting element ED22 and the second light control element L22 of the second subpixel SP2 may be equal to or smaller than the size (number) of the second light emitting element ED32 and the second light control element L33 of the third subpixel SP3.

In the first viewing angle control mode, the first to third subpixels SP1, SP2, and SP3 drive the first light emitting elements ED11, ED21, and ED31 and do not limit the path of light emitted from each of the first light emitting elements ED11 and ED21, ED31 to within a specific angle in the first direction X through the first light control elements L11, L21, and L31, thereby providing light having a wide viewing angle.

In the second viewing angle control mode, the first to third subpixels SP1, SP2, and SP3 drive the second light emitting elements ED12, ED22, and ED32 and, through the second light control elements L12, L22, and L32, limit the path of light emitted from each of the second light emitting elements ED12, ED22, and ED32 to within a specific angle in the first direction X, thereby providing light having a narrow viewing angle.

The first light control element L1: L11, L21, and L31 and the second light control element L2: L12, L22, and L32 may control the light propagation path in the second direction Y to a narrow viewing angle by limiting it to a specific angle. Accordingly, in one embodiment, when the display apparatus 1000 is applied to a vehicle, the image displayed on the display apparatus 1000 may be prevented from being reflected by the windshield of the vehicle and obstructing the driver's view.

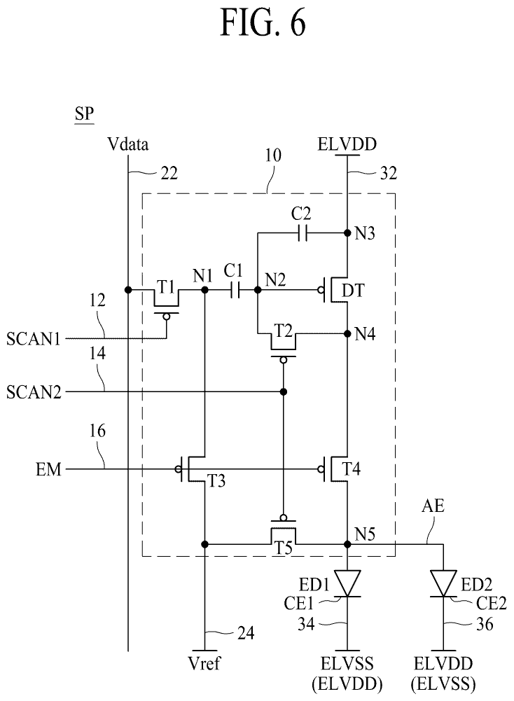

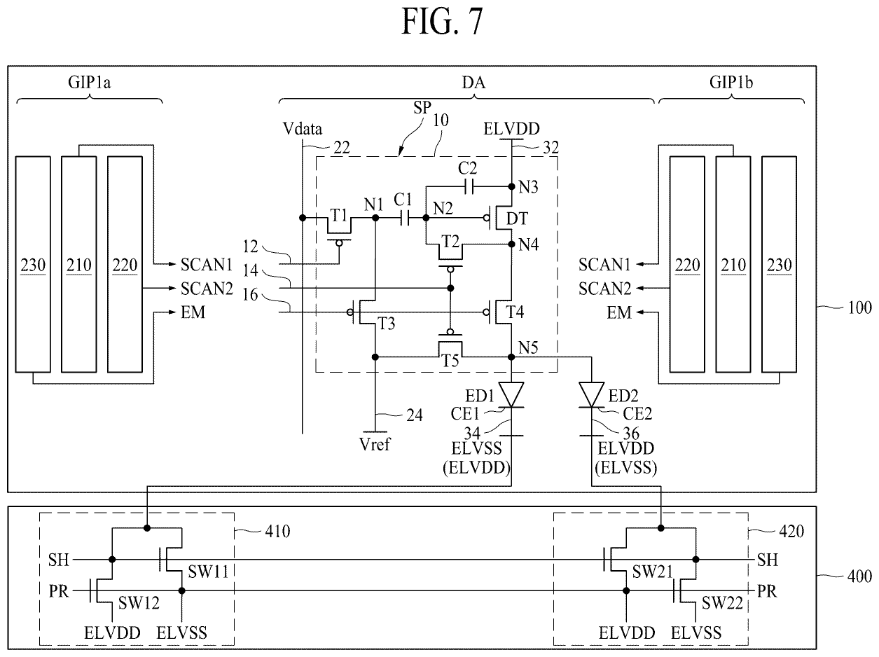

FIG. 6 is an equivalent circuit diagram illustrating a subpixel configuration according to one embodiment of the present disclosure, and FIG. 7 is a diagram schematically illustrating a gate driving circuit and a power management circuit configuration according to one embodiment of the present disclosure.

Referring to FIG. 6, a subpixel SP may include first and second light emitting elements ED1, ED2 and a pixel circuit 10 connected to the first and second light emitting elements ED1 and ED2. In one embodiment, the pixel circuit 10 may include a driving transistor DT, a plurality of switching transistors T1 to T5, and a plurality of capacitors C1 and C2, but is not limited to this configuration.

The pixel circuit 10 may receive a first scan signal SCAN1 from a first scan driving circuit 210 through a first gate line 12, a second scan signal SCAN2 from a second scan driving circuit 220 through a second gate line 14, and a light emission control signal EM from a light emission control driving circuit 230 through a third gate line 16.

Referring to FIG. 7, the gate driving circuit may include first and second driving circuits GIP1a and GIP1b arranged in non-display areas on both sides of the display area, respectively. Each of the first and second gate driving circuits GIP1a and GIP1b may include a first scan driving circuit 210, a second scan driving circuit 220, and a light emission control driving circuit 230.

The power management circuit 400 may include a first switching unit 410 that selectively applies the high-potential power voltage ELVDD or the low-potential power voltage ELVSS to the first cathode electrode CE1 through a second power line 34 according to a viewing angle control mode; and a second switching unit 420 that selectively applies the high-potential power voltage ELVDD or the low-potential power voltage ELVSS to the second cathode electrode CE2 through a third power line 36 according to the viewing angle control mode, and a power voltage applied to the second cathode electrode CE2 may be opposite to that applied to the first cathode electrode CE1 of the first light emitting element ED1.

The pixel circuit 10 may receive a data signal Vdata from a data driving circuit through a data line 22. The pixel circuit 10 may receive the high-potential power voltage ELVDD through a first power line 32 from the power management circuit 400 and may receive a reference voltage Vref through a reference line 24 from the power management circuit 400.

The driving transistor DT and the plurality of switching transistors T1 to T5 each of the pixel circuit 10 include a gate electrode, a source electrode, and a drain electrode. Since the source electrode and the drain electrode are not fixed and may be changed depending on the voltage and current direction applied to the gate electrode, one of the source electrode and the drain electrode may be expressed as a first electrode, and the other may be expressed as a second electrode. The driving transistor DT and the plurality of switching transistors T1 to T5 of the pixel circuit 10 may use at least one of a polysilicon semiconductor, an amorphous silicon semiconductor, and an oxide semiconductor, and may use of P type or N type, or a mixture of P type and N type.

The first and second light emitting elements ED1 and ED2 may have an anode electrode AE commonly connected to the fourth switching transistor T4, first and second cathode electrodes CE1 and CE2 respectively connected to the second and third power lines 34 and 36, and a light emitting layer between the anode electrode AE and the cathode electrode CE1 and CE2. When a driving current is supplied from the driving transistor DT through the fourth switching transistor T4, each of the first and second light emitting elements ED1 and ED2 injects electrons from one of the cathode electrodes CE1 and CE2 into the light emitting layer, and injects holes from the anode electrode AE into the organic light emitting layer, thereby causing a fluorescent or phosphorescent material to emit light through recombination of electrons and holes in the light emitting layer, thereby emitting light having a brightness proportional to the current value of the driving current.

The gate electrode of the driving transistor DT is connected to a first capacitor C1 through a second node N2, the first electrode of the driving transistor DT is connected to a first power line 32 that supplies the high-potential power voltage ELVDD, through a third node N3, and the second electrode of the driving transistor DT may be commonly connected to the second and fourth switching transistors T2 and T4 through a fourth node N4. A second capacitor C2 is further connected between the gate electrode of the driving transistor DT and the first power line 32 to stably maintain the gate voltage of the driving transistor DT.

The driving transistor DT may drive the first light emitting element ED1 or the second light emitting element ED2 through the fourth switching transistor T4. The driving transistor DT may control the light emitting intensity of the first light emitting element ED1 or the light emitting intensity of the second light emitting element ED2 by controlling the driving current according to the driving voltage charged in the first capacitor C1.

The first capacitor C1 is connected between a first node N1 connected to the second electrode of the first switching transistor T1 and the second node N2 connected to the gate electrode of the driving transistor DT and may charge a driving voltage corresponding to the data voltage Vdata. The first capacitor C1 may hold the charged driving voltage during the light emission period t3 in which the first switching transistor T1 is turned off and supply the voltage to the driving transistor DT.

The first switching transistor T1 may be turned on or off in response to a first scan signal SCAN1 of the first gate line 12. The first switching transistor T1 may supply a data voltage Vdata supplied through the data line 22 to the first electrode of the first capacitor (also known as storage capacitor) C1 during a sampling and writing period in which the first scan signal SCAN1 has a gate-on voltage. The switching transistor T1 may be turned off during an initialization period and a light emission period in which the first scan signal SCAN1 has a gate-off voltage.

The second and fifth switching transistors T2 and T5 may be turned on or off in response to the second scan signal SCAN2 supplied to the second gate line 14. The second and fifth switching transistors T2 and T5 may be turned on during the initialization period and the sampling and writing emission period in which the second scan signal SCAN2 has the gate-on voltage, and may be turned off during the light emitting period in which the second scan signal SCAN2 has the gate-off voltage.

The second switching transistor T2 may connect the gate electrode and the second electrode of the driving transistor DT during the initialization period and the sampling and writing emission period in response to the second scan signal SCAN2, thereby connecting the driving transistor DT in a diode structure. The second switching transistor T2 may compensate for the threshold voltage Vth of the driving transistor DT by charging the threshold voltage Vth in the first capacitor C1. Accordingly, the first capacitor C1 may charge the data voltage for which the threshold voltage Vth of the driving transistor DT is compensated.

The fifth switching transistor T5 may supply the reference voltage Vref supplied through the reference line 24 to the anode electrode AE of the first and second light emitting elements ED1 and ED2 through a fifth node N5 during the initialization period and the sampling and writing period in response to the second scan signal SCAN2.

The third switching transistor T3 may be turned on or off in response to the light emission control signal EM supplied to the third gate line 16. The third switching transistor T3 may be turned on during the initialization period and the light emission period in which the light emission control signal EM has the gate-on voltage. The third switching transistor T3 may supply the reference voltage Vref supplied through the reference line 24 to the first electrode of the first capacitor C1 during the initialization period and the light emission period in response to the light emission control signal EM.

The fourth switching transistor T4 may be turned on or off in response to the light emission control signal EM supplied to the third gate line 16. The fourth switching transistor T4 may be turned on during the initialization period and the light emission period in which the light emission control signal EM has a gate-on voltage. The fourth switching transistor T4 may connect the driving transistor DT to the first and second light emitting elements ED1 and ED2 through the fifth node N5 during the initialization period and the light emission period in response to the light emission control signal EM.

The first cathode electrode CE1 of the first light emitting element ED1 and the second cathode electrode CE2 of the second light emitting element ED2 are separated so that the first light emitting element ED1 and the second light emitting element ED2 may be driven independently according to the viewing angle control mode.

The first switching unit 410 of the power management circuit 400 may include first and second switches SW11 and SW12 that selectively output the low-potential power voltage ELVDD or the high-potential power voltage ELVDD to the second power line 34 in response to a viewing angle control mode control signal SH and PR.

The second switching unit 420 of the power management circuit 400 may include first and second switches SW21 and SW22 that selectively output the high-potential power voltage ELVDD or the low-potential power voltage ELVSS to the third power line 36 in response to a viewing angle control mode control signal SH and PR.

The power management circuit 400 may supply the low-potential power voltage ELVSS to the second power line 34 and the high-potential power voltage ELVDD to the third power line 36 in response to the first viewing angle control mode control signal SH. Accordingly, in the first viewing angle control mode, the low-potential power voltage ELVSS is supplied to the first cathode electrode CE1 of the first light emitting element ED1, so that the first light emitting element ED1 may emit light by driving of the pixel circuit 10, whereas the high-potential power voltage ELVDD is supplied to the second cathode electrode CE2 of the second light emitting element ED2, so that emission of the second light emitting element ED2 may be prevented.

The power management circuit 400 may supply the high-potential power voltage ELVDD to the second power line 34 and the low-potential power voltage ELVSS to the third power line 36 in response to the second viewing angle control mode control signal PR. Accordingly, in the second viewing angle control mode, the low-potential power voltage ELVSS is supplied to the second cathode electrode CE2 of the second light emitting element ED2, so that the second light emitting element ED2 may emit light by driving of the pixel circuit 10, whereas the high-potential power voltage ELVDD is supplied to the first cathode electrode CE1 of the first light emitting element ED1, so that emission of the first light emitting element ED2 may be prevented.

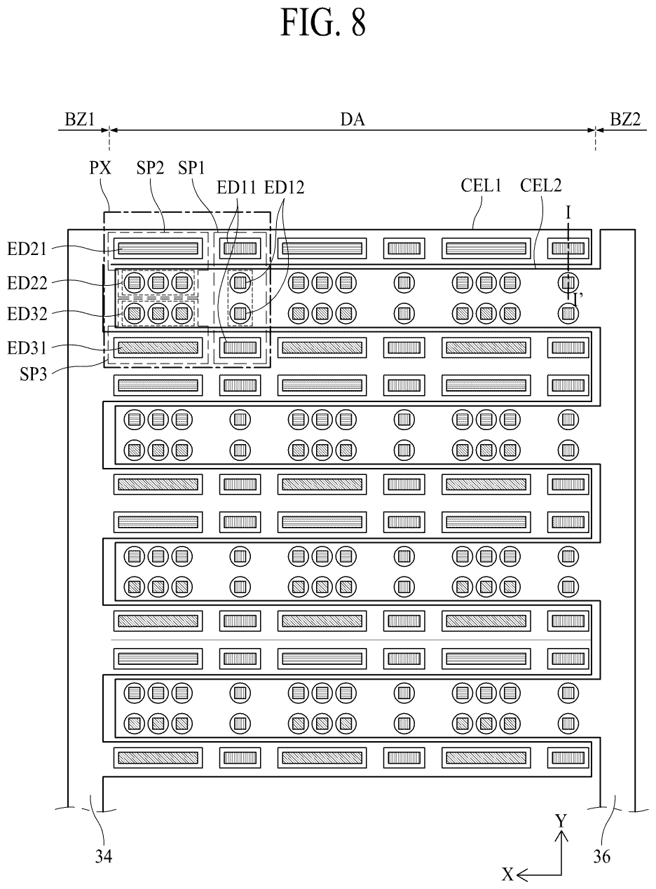

FIG. 8 is a drawing illustrating a cathode electrode division structure of a display apparatus according to one embodiment of the present disclosure.

Referring to FIG. 8, the display apparatus according to one embodiment may include a first cathode electrode line CEL1 commonly connected to a plurality of first light emitting elements ED11, ED21 and ED31 in a plurality of subpixels, and a second cathode electrode line CEL2 commonly connected to a plurality of second light emitting elements ED12, ED22 and ED32.

In the display area DA of a display panel 100, a plurality of first cathode electrode lines CEL1 and a plurality of second cathode electrode lines CEL2 may be alternately arranged along a second direction Y. The plurality of first cathode electrode lines CEL1 may extend along the first direction X and be commonly connected to a second power line 34 extending in the second direction Y in a first bezel area BZ1 of the display panel 100. The plurality of second cathode electrode lines CEL2 may extend along the first direction X and be commonly connected to a third power line 36 extending in the second direction Y in a second bezel area BZ2 of the display panel 100.

According to the viewing angle mode, the low-potential power voltage ELVSS or the high-potential power voltage ELVDD may be selectively applied to the first cathode electrode line CEL1 through the second power line 34, and the high-potential power voltage ELVDD or the low-potential power voltage ELVSS may be selectively applied to the second cathode electrode line CEL2 through the third power line 36.

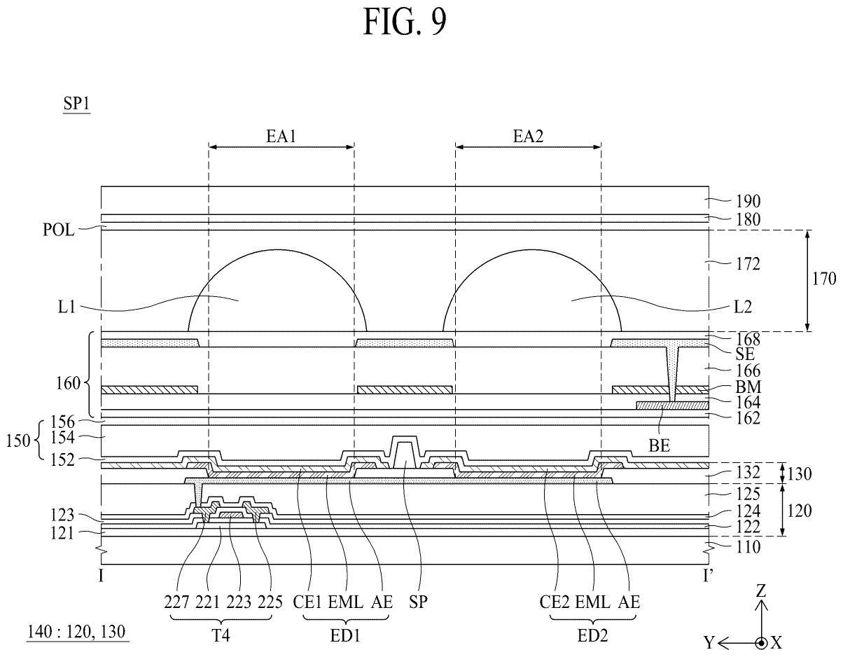

FIG. 9 is a cross-sectional view illustrating the structure of a subpixel according to one embodiment of the present disclosure.

Referring to FIG. 9, a display panel 100 according to one embodiment may include a pixel array 140 including a circuit element layer 120 on a substrate 110 and a light emitting element layer 130 on the circuit element layer 120, an encapsulation layer 150 disposed to seal the light emitting element layer 130 on the pixel array 140, a touch sensor array 160 on the encapsulation layer 150, and a light control array 170 on the touch sensor array 160. The display panel 100 may further include a polarizing plate POL, an optically clear adhesive (OCA) 180, a cover substrate 190, etc., disposed on the light control array 170.

Referring to FIG. 9, the cross-sectional structure of the first subpixel SP1 among the first to third subpixels SP1, SP2, and SP3 in the display panel 100 as shown in FIG. 8 according to one embodiment will be described as an example. The first to third subpixels SP1, SP2, and SP3 may have the same cross-sectional structure.

Each subpixel represented by the first subpixel SP1, may include a thin film transistor T4 of a pixel circuit 10, a first light emitting element ED1 and a second light emitting element ED2 connected to the thin film transistor T4, a first light control element L1 arranged to overlap a light emitting area EA1 on the first light emitting element ED1, and a second light control element L2 disposed to overlap a light emitting area EA2 on the second light emitting element ED2.

A circuit element layer 120 according to one embodiment may include a plurality of insulating layers stacked on a substrate 110. For example, the plurality of insulating layers may include a buffer layer 121, a gate insulating layer 122, an interlayer insulating layer 123, a passivation layer 124, and a planarization layer 125.

The substrate 110 may include an insulating material such as glass or plastic. The plastic substrate may be formed of a flexible material. For example, the substrate 110 may include at least one organic insulating material selected from the group consisting of acrylic resin, epoxy resin, siloxane resin, polyimide resin, and polyamide resin.

The buffer layer 121 may have a single layer or multi-layer structure including an inorganic insulating material such as silicon oxide (SiOx), silicon nitride (SiNx), or aluminum oxide (Al₂O₃). The buffer layer 121 may prevent impurities such as hydrogen from flowing into the semiconductor layer 221 through the substrate 110.

The plurality of thin film transistors including the thin film transistor T4 may be disposed on the buffer layer 121.

In one embodiment, the buffer layer 121 may include a multi-buffer layer and an active buffer layer. In this case, the multi-buffer layer may be disposed on the substrate 110, and the active buffer layer may be disposed on the multi-buffer layer. A light shielding layer may be disposed between the multi-buffer layer and the active buffer layer.

The thin film transistor T4 includes a semiconductor layer 221, a gate electrode 223, a source electrode 225, and a drain electrode 227, each of which is disposed over the buffer layer 121. The gate insulating layer 122 is disposed between the semiconductor layer 221 and the gate electrode 223. The interlayer insulating layer 123 is disposed between the gate electrode 223 and the source and drain electrodes 225 and 227. The source electrode 225 and the drain electrode 227 may be connected to the source region and the drain region of the semiconductor layer 221 through contact holes penetrating the interlayer insulating layer 123 and the gate insulating layer 122, respectively.

The semiconductor layer 221 may include polycrystalline silicon or an oxide semiconductor material. The semiconductor layer 221 may include low-temperature polysilicon LTPS. The semiconductor layer 221 may include at least one oxide semiconductor material from among IZO (InZnO) based, IGO (InGaO) based, ITO (InSnO) based, IGZO (InGaZnO) based, IGZTO (InGaZnSnO) based, GZTO (GaZnSnO) based, GZO (GaZnO) based, and ITZO (InSnZnO) based oxide semiconductor material. A light shielding layer (not shown) may be further disposed under the semiconductor layer 221.

The gate insulating layer 122 may include an inorganic insulating material such as silicon oxide (SiOx) and silicon nitride (SiNx). The gate insulating layer 122 may include a material having a high dielectric constant. For example, the gate insulating layer 122 may include a high-K material such as hafnium oxide (HfO). The gate insulating layer 122 may have a multilayer structure.

A gate electrode 223 and a gate line may be disposed on the gate insulating layer 122.

The interlayer insulating layer 123 may include an inorganic insulating material such as silicon oxide (SiOx) and silicon nitride (SiNx). The interlayer insulating layer 123 may have a multilayer structure.

A source electrode 225 and a drain electrode 227 and data lines and power lines may be arranged on the interlayer insulating layer 123.

A passivation layer 124 and a planarization layer 125 may be stacked on the thin film transistor T4. The passivation layer 124 may include an inorganic insulating material such as silicon oxide (SiOx) and silicon nitride (SiNx). The planarization layer 125 may include an organic insulating material different from the passivation layer 124 and may provide a planar surface. The planarization layer 125 may have a double-layer structure.

A light emitting element layer 130 including light emitting elements ED1 and ED2 may be disposed on the planarization layer 125.

Each of the first and second light emitting elements ED1 and ED2 may include an anode electrode AE, which may also called common anode electrode AE, disposed on a planarization layer 125, a light emitting stack EML disposed on the anode electrode AE, and first and second cathode electrodes CE1 and CE2 disposed on the light emitting stack EML, respectively. So the common anode electrode AE overlaps the first and second light emitting elements ED1 and ED2.

The anode electrode AE of the first and second light emitting elements ED1 and ED2 may be connected to one of the source electrode 225 and the drain electrode 227 of the transistor T4 through a contact hole penetrating the planarization layer 125 and the passivation layer 124. The first and second light emitting elements ED1 and ED2 may share the anode electrode AE. The anode electrode AE may include a conductive material having high reflectivity. The anode electrode AE may include a metal such as aluminum (Al), silver (Ag), titanium (Ti), or a silver-palladium-copper (APC) alloy. The anode electrode AE may further include a transparent conductive material such as indium tin oxide (ITO) or indium zinc oxide (IZO). In one embodiment, the anode electrode AE may have a multilayer structure (Ti/Al/Ti) of titanium (Ti) and aluminum (Al), a multilayer structure (ITO/Al/ITO) of ITO and aluminum (Al), or a multilayer structure (ITO/APC/ITO) of ITO and APC.

The light emitting stack EML may include a layer of an emission material including an emission material. The emission material may include an organic material, an inorganic material, or a hybrid material. The light emitting stack EML may have a multilayer structure. In one embodiment, the light emitting stack EML may further include at least one of a hole injection layer HIL, a hole transport layer HTL, an electron transport layer ETL, and an electron injection layer EIL.

The first and second cathode electrodes CE1 and CE2 may include a conductive material that transmits light. The first and second cathode electrodes CE1 and CE2 may include a transparent conductive material such as ITO or IZO. The first and second cathode electrodes CE1 and CE2 may include aluminum (Al), magnesium (Mg), silver (Ag), or an alloy thereof, and may have a thin thickness that transmits light.

The bank insulating layer 132 defining light emitting areas EA1 and EA2 may be disposed on the anode electrode AE of the first and second light emitting elements ED1 and ED2. The bank insulating layer 132 may cover an edge of the anode electrode AE and may cover a middle portion of the anode electrode AE to separate the light emitting areas EA1 and EA2. The bank insulating layer 132 may include an organic insulating material. The bank insulating layer 132 may include an organic material different from the planarization layer 125 and may have a single layer or double layer structure. A spacer SP may be further disposed on the bank insulating layer 132.

The bank insulating layer 132 may have a plurality of openings through which the anode electrode AE of the first and second light emitting elements ED1 and ED2 are exposed, thereby defining a plurality of light emitting areas EA1 and EA2. The light emitting stack EML and the cathode electrodes CE1 and CE2 of the first and second light emitting elements ED1 and ED2 may be stacked on the anode electrode AE exposed by the openings of the bank insulating layer 132. The first and second cathode electrodes CE1 and CE2 of the first and second light emitting elements ED1 and ED2 may be separated by the spacer SP.

An encapsulation layer 150 may be disposed on a light emitting element layer 130 including first and second light emitting elements ED1 and ED2. The encapsulation layer 150 may prevent damage to the light emitting elements ED1 and ED2 due to moisture and impact from the outside. The encapsulation layer 150 may have a multi-layer structure. In one embodiment, the encapsulation layer 150 may include a first encapsulation layer 152, a second encapsulation layer 154, and a third encapsulation layer 156 that are sequentially stacked, but is not limited thereto. The first encapsulation layer 152, the second encapsulation layer 154, and the third encapsulation layer 156 may include an insulating material. The second encapsulation layer 154 may include a different material from the first encapsulation layer 152 and the third encapsulation layer 156. For example, the first sealing layer 152 and the third sealing layer 156 may be inorganic sealing layers including an inorganic insulating material, and the second sealing layer 154 may be an organic sealing layer including an organic insulating material. Accordingly, the light emitting elements ED1 and ED2 of the display apparatus may be more effectively prevented from damage due to moisture and impact from the outside.

The touch sensor array 160 may include a first touch insulating layer 162 disposed on an encapsulating layer 150, a bridge electrode BE disposed on the first touch insulating layer 162, a second touch insulating layer 164 covering the bridge electrode BE, a black matrix BM disposed on the second touch insulating layer 164, a third touch insulating layer 166 covering the black matrix BM and a sensor electrode SE disposed on the third touch insulating layer 166, and a fourth touch insulating layer 168 covering the sensor electrode SE. The bridge electrode BE, the black matrix BM, and the sensor electrode SE may be disposed in a non-light emitting region overlapping the bank insulating layer 132.

At least one end of the sensor electrode SE and the black matrix BM may overlap the ends of the first and second light control elements L1 and L2 in the non-light emitting region.

The light control array 170 may be disposed on top of touch a sensor array 160. The light control array 170 may include light control elements L1 and L2 disposed on the touch sensor array 160 and a passivation layer 172 covering the light control elements L1 and L2.

The first light control element L1 is disposed on the light emitting area EA1 of the first light emitting element ED1, and the second light control element L2 is disposed on the light emitting area EA2 of the second light emitting element ED2, so that the path of light generated in the light emitting areas EA1, EA2 may be controlled.

The first light control element L1 may control the propagation path of light generated in the light emitting area EA1 of the first light emitting element ED1 with a wide viewing angle in the first direction X and with a narrow viewing angle in the second direction Y. The second light control element L2 may control the propagation path of light generated in the light emitting area EA2 of the second light emitting element ED22 with a narrow viewing angle in the first and second directions X and Y.

The passivation layer 172 covering the light control elements L1 and L2 may include an organic insulating material. The refractive index of the passivation layer 172 may be lower than the refractive index of the light control elements L1 and L2. Accordingly, light passing through the light control elements L1 and L2 may not be reflected toward the substrate 110 due to the difference in refractive index with respect to the passivation layer 172.

As described above, the display apparatus according to one embodiment of the present disclosure may control the viewing angle of each subpixel by providing separated the first cathode electrode for the first light emitting element providing a wide viewing angle through the first lens and a separated or independently controllable the second cathode electrode of the second light emitting element providing a narrow viewing angle through the second lens, and independently driving the first and second light emitting elements by changing the voltages of the first and second cathode electrodes.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the scope of the present disclosure includes those represented by the following claims, and all changes or modifications derived from the meaning, range and equivalent concept of the claims should be interpreted as being included in the scope of the present disclosure.

In certain embodiments, a display apparatus may include a display panel having a plurality of subpixels. Each subpixel may include a first light emitting element and a second light emitting element. The first and second light emitting elements may include respective first and second cathode electrodes that are physically and electrically separated from each other. A power management circuit may be provided and configured to selectively apply a first supply voltage and a second supply voltage to the first and second cathode electrodes to switch between a first viewing angle mode and a second viewing angle mode. In the first viewing angle mode, the power management circuit may apply the first supply voltage to the first cathode electrode and the second supply voltage to the second cathode electrode, and in the second viewing angle mode, the power management circuit may apply the second supply voltage to the first cathode electrode and the first supply voltage to the second cathode electrode. By varying the voltages applied to the cathode electrodes in this manner, one of the first and second light emitting elements may emit light corresponding to the selected viewing angle mode.

In some embodiments, the power management circuit may comprise a first switching unit connected to the first cathode electrode and configured to selectively output either the first supply voltage or the second supply voltage, and a second switching unit connected to the second cathode electrode and configured to selectively output either the first supply voltage or the second supply voltage. The first and second switching units may be operated in a complementary fashion such that, in the first viewing angle mode, the first switching unit outputs the first supply voltage and the second switching unit outputs the second supply voltage, and in the second viewing angle mode, the first switching unit outputs the second supply voltage and the second switching unit outputs the first supply voltage. This complementary switching operation may enable selective activation of either the first or second light emitting element to achieve the desired viewing angle characteristics.

Each subpixel of the display panel may further include a first lens disposed over the first light emitting element and a second lens disposed over the second light emitting element. The first lens may be configured to provide a wide viewing angle, and the second lens may be configured to provide a narrower viewing angle than the first lens. Accordingly, the first viewing angle mode may correspond to a wide viewing angle produced by the first lens, and the second viewing angle mode may correspond to a narrow viewing angle produced by the second lens.

In another embodiment, a display apparatus may include a display panel having a plurality of subpixels, each subpixel including a first light emitting element configured to provide a wide viewing angle and a second light emitting element configured to provide a narrow viewing angle. The apparatus may further include a power management circuit configured to independently drive the first and second light emitting elements by reversing supply polarities of their respective cathode electrodes to switch between a share mode and a privacy mode. In the share mode, the first light emitting element may be driven while the second light emitting element is deactivated, and in the privacy mode, the second light emitting element may be driven while the first light emitting element is deactivated. Through this control, the display apparatus may electronically change its viewing angle characteristics without reliance on a separate privacy film or external optical filter.

In certain embodiments, the power management circuit may include a first switching unit connected to the first cathode electrode and configured to selectively output a first supply voltage or a second supply voltage, and a second switching unit connected to the second cathode electrode and configured to selectively output the first supply voltage or the second supply voltage. The first and second switching units may operate complementarily to reverse the supply polarities of the respective cathode electrodes according to whether the apparatus is in the share mode or the privacy mode.

Each subpixel of the display panel may include a first lens positioned on the first light emitting element to provide the wide viewing angle and a second lens positioned on the second light emitting element to provide the narrow viewing angle. The optical properties of the lenses may be selected such that the first lens produces a wider emission profile and the second lens restricts emission to a narrower angular range, thereby enabling the display apparatus to present an image viewable from wide or narrow directions depending on the selected mode.

In some embodiments, the display panel may include a plurality of first cathode electrode lines connected to the first light emitting elements of the plurality of subpixels and a plurality of second cathode electrode lines connected to the second light emitting elements of the plurality of subpixels. The first and second cathode electrode lines may be alternately arranged in the display area so that each type of light emitting element can be selectively driven according to the viewing mode. This alternating structure may assist in achieving uniform emission and electrical isolation between the respective electrode systems.

In certain embodiments, the display apparatus may be configured to switch between the share mode and the privacy mode electronically, without the use of any external optical film or removable privacy filter. By integrating the viewing angle control function into the emissive structure and driving circuitry, the display may maintain high brightness and color quality while providing electronic privacy control.

In other embodiments, the display apparatus may further include a plurality of first cathode electrode lines disposed in the display area, each first cathode electrode line being connected to a respective first cathode electrode to commonly drive the first light emitting elements of the plurality of subpixels, and a plurality of second cathode electrode lines disposed in the display area, each second cathode electrode line being connected to a respective second cathode electrode to commonly drive the second light emitting elements of the plurality of subpixels. A second power line may be commonly connected to the plurality of first cathode electrode lines in a first bezel area outside the display area, and a third power line may be commonly connected to the plurality of second cathode electrode lines in a second bezel area outside the display area. This electrode and power line arrangement may facilitate efficient routing of driving voltages to the respective cathode electrodes while maintaining compact bezel design and reliable electrical isolation.

The various embodiments described above may be combined to provide further embodiments. Aspects of the embodiments may be modified, if necessary to employ concepts of the various embodiments to provide yet further embodiments.

These and other changes may be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display area having a plurality of subpixels,
wherein each of the plurality of subpixels includes:
a first light emitting element;
a second light emitting element; and
a pixel circuit commonly connected to the first and second light emitting elements;
wherein:
a first cathode electrode of the first light emitting element and a second cathode electrode of the second light emitting element are separated from each other; and
power supply voltages applied to the first and second cathode electrodes are varied according to a viewing angle control mode.

2. The display apparatus of claim 1,
wherein each of the plurality of subpixels comprises:
a first lens disposed over the first light emitting element; and
a second lens disposed over the second light emitting element,
wherein the first and second lenses provide different viewing angles.

3. The display apparatus of claim 2,
wherein a size of a lower surface of the first lens is larger than a size of a light emitting area of the first light emitting element; and
a size of a lower surface of the second lens is larger than a size of a light emitting area of the second light emitting element.

4. The display apparatus of claim 2,
wherein the first lens has a half-cylindrical lens structure that is elongated in a first direction; and
the second lens has a half-spherical lens structure.

5. The display apparatus of claim 1, wherein, in a first viewing angle control mode, a low-potential supply voltage among the power supply voltages is applied to the first cathode electrode and a high-potential supply voltage among the power supply voltages is applied to the second cathode electrode, whereby the first light emitting element is driven by the pixel circuit to emit light.

6. The display apparatus of claim 1, wherein, in a second viewing angle control mode, a high-potential supply voltage among the power supply voltages is applied to the first cathode electrode and a low-potential supply voltage among the power supply voltages is applied to the second cathode electrode, whereby the second light emitting element is driven by the pixel circuit to emit light.

7. The display apparatus of claim 1, further comprising a bank insulating layer,
wherein:
the first and second light emitting elements share an anode electrode connected to the pixel circuit, and
the first and second light emitting elements include respective light emitting stacks disposed in first and second emission regions that are separated by the bank insulating layer.

8. The display apparatus of claim 7, wherein the first and second cathode electrodes are separated by a spacer disposed on the bank insulating layer.

9. The display apparatus of claim 1 further comprising:
a power management circuit including:
a first switching unit configured to selectively apply a high-potential supply voltage among the power supply voltages or a low-potential supply voltage among the power supply voltages to the first cathode electrode according to the viewing angle control mode; and
a second switching unit configured to selectively apply the high-potential supply voltage or the low-potential supply voltage to the second cathode electrode according to the viewing angle control mode.

10. The display apparatus of claim 9, wherein, in response to a first viewing angle control mode signal,
the first switching unit applies the low-potential supply voltage to the first cathode electrode, and
the second switching unit applies the high-potential supply voltage to the second cathode electrode.

11. The display apparatus of claim 9, wherein, in response to a second viewing angle control mode signal,
the first switching unit applies the high-potential supply voltage to the first cathode electrode, and
the second switching unit applies the low-potential supply voltage to the second cathode electrode.

12. The display apparatus of claim 1, further comprising:
a plurality of first cathode electrode lines disposed in the display area including the first cathode electrode to be shared by the first light emitting elements of the plurality of subpixels;
a plurality of second cathode electrode lines disposed in the display area including the second cathode electrode to be shared by the second light emitting elements of the plurality of subpixels;
a second power line commonly connecting to the plurality of first cathode electrode lines in a first bezel area outside of the display area, and
a third power line commonly connecting to the plurality of second cathode electrode lines in a second bezel area outside of the display area.

13. The display apparatus of claim 1, wherein the pixel circuit comprises:
a driving transistor;
a storage capacitor connected to a gate electrode of the driving transistor;
a first switching transistor supplying a data voltage of a data line to a first electrode of the storage capacitor in response to a first scan signal of a first gate line;
a second switching transistor diode-connecting the driving transistor in response to a second scan signal of a second gate line;
a third switching transistor supplying an initialization voltage of an initialization voltage line to the first electrode of the storage capacitor in response to an emission control signal of a third gate line,
a fourth switching transistor connecting the driving transistor to the first and second light emitting elements in response to the emission control signal of the third gate line; and
a fifth switching transistor supplying the initialization voltage of the initialization voltage line to anodes of the first and second light emitting elements in response to the second scan signal of the second gate line.

14. A display apparatus comprising:
a display panel including a plurality of subpixels, each subpixel comprising a first light emitting element and a second light emitting element having respective first and second cathode electrodes separated from each other; and
a power management circuit configured to selectively apply a first supply voltage or a second supply voltage to one of the first and second cathode electrodes to switch between a first viewing angle mode and a second viewing angle mode,
wherein:
in the first viewing angle mode, the power management circuit applies the first supply voltage to the first cathode electrode and the second supply voltage to the second cathode electrode, and
in the second viewing angle mode, the power management circuit applies the second supply voltage to the first cathode electrode and the first supply voltage to the second cathode electrode,
thereby causing one of the first and second light emitting elements to emit light corresponding to the selected viewing angle mode.

15. The display apparatus of claim 14, wherein the power management circuit comprises:
a first switching unit connected to the first cathode electrode and configured to selectively output the first supply voltage or the second supply voltage; and
a second switching unit connected to the second cathode electrode and configured to selectively output the first supply voltage or the second supply voltage,
wherein the first and second switching units operate complementarily so that, in the first viewing angle mode, the first switching unit outputs the first supply voltage and the second switching unit outputs the second supply voltage, and in the second viewing angle mode, the first switching unit outputs the second supply voltage and the second switching unit outputs the first supply voltage.

16. The display apparatus of claim 14, wherein each subpixel further comprises:
a first lens disposed on the first light emitting element to provide a wide viewing angle; and
a second lens disposed on the second light emitting element to provide a narrow viewing angle narrower than the first lens,
wherein the first viewing angle mode provides the wide viewing angle and the second viewing angle mode provides the narrow viewing angle.

17. A display apparatus comprising:
a display panel including a plurality of subpixels, each subpixel comprising a first light emitting element configured to provide a wide viewing angle and a second light emitting element configured to provide a narrow viewing angle; and
a power management circuit configured to independently drive the first and second light emitting elements by reversing supply polarities of respective cathode electrodes to switch between a share mode and a privacy mode,
wherein:
in the share mode, the first light emitting element is driven and the second light emitting element is deactivated; and
in the privacy mode, the second light emitting element is driven and the first light emitting element is deactivated.

18. The display apparatus of claim 17,
wherein the power management circuit comprises:
a first switching unit connected to a first cathode electrode of the first light emitting element and configured to selectively output a first supply voltage or a second supply voltage; and
a second switching unit connected to a second cathode electrode of the second light emitting element and configured to selectively output the first supply voltage or the second supply voltage,
wherein the first and second switching units operate complementarily to reverse the supply polarities of the respective cathode electrodes according to the share mode and the privacy mode.

19. The display apparatus of claim 17,
wherein each subpixel further comprises:
a first lens disposed on the first light emitting element to provide the wide viewing angle; and
a second lens disposed on the second light emitting element to provide the narrow viewing angle.

20. The display apparatus of claim 17,
wherein the display panel comprises:
a plurality of first cathode electrode lines connected to the first light emitting elements of the plurality of subpixels; and
a plurality of second cathode electrode lines connected to the second light emitting elements of the plurality of subpixels,
the first and second cathode electrode lines being alternately arranged in the display area.

21. The display apparatus of claim 17, wherein the display apparatus switches between the share mode and the privacy mode electronically without use of an external optical film.

22. The display apparatus of claim 17, further comprising:
a plurality of first cathode electrode lines disposed in the display area, each first cathode electrode line being connected to a respective first cathode electrode to commonly drive the first light emitting elements of the plurality of subpixels;
a plurality of second cathode electrode lines disposed in the display area, each second cathode electrode line being connected to a respective second cathode electrode to commonly drive the second light emitting elements of the plurality of subpixels;
a second power line commonly connected to the plurality of first cathode electrode lines in a first bezel area outside the display area; and
a third power line commonly connected to the plurality of second cathode electrode lines in a second bezel area outside the display area.
